(19) United States
(12) Patent Application Publication
(10) Pub. No.: US 2023/0253762 A1
(43) Pub. Date: Aug. 10, 2023

(54) SEMICONDUCTOR LASER DEVICE

(71) Applicant: FURUKAWA ELECTRIC CO., LTD., Tokyo (JP)

(72) Inventor: Masaki WAKABA, Tokyo (JP)

(73) Assignee: FURUKAWA ELECTRIC CO., LTD., Tokyo (JP)

(21) Appl. No.: 18/156,641

(22) Filed: Jan. 19, 2023

(30) Foreign Application Priority Data
Feb. 10, 2022 (JP) 2022-019576

(51) Int. Cl. H01S 5/227; H01S 5/343; H01S 5/10; H01S 5/22

(52) U.S. Cl. CPC H01S 5/227; H01S 5/3434; H01S 5/1014; H01S 5/2206; H01S 5/34373

(57) ABSTRACT

A semiconductor laser device includes: a main body including a first layer having n-type conductivity, a second layer having p-type conductivity, and an active layer interposed between the first layer and the second layer, the first layer, the second layer, and the active layer being laminated in a lamination direction; a front-side mirror formed on a front facet of the main body, the front facet being parallel to the lamination direction; and a rear-side mirror formed on a rear facet of the main body, the rear facet facing the front facet in an optical waveguide direction that crosses the lamination direction and the front facet. The first layer includes an electric field control layer having a shorter composition wavelength than an emission wavelength of the active layer. The second layer includes an optical guide layer having a shorter composition wavelength than the emission wavelength of the active layer.

This application claims the benefit of priority from Japanese Patent Application No. 2022-019576 filed on Feb. 10, 2022, the entire contents of which are incorporated herein by reference.

### BACKGROUND

The present disclosure relates to a semiconductor laser device.

A semiconductor laser device that is used as what is called a pump laser in an Erbium-doped optical fiber amplifier and a Raman amplifier is always demanded to achieve high output and low power consumption.

To achieve high output of the semiconductor laser device, it is effective to reduce an internal loss and improve extraction efficiency of laser light from the device. To improve the extraction efficiency, it is effective to reduce a ratio Pr/Pf of optical power Pr from a rear facet of the semiconductor laser device to optical power Pf of a front facet of the semiconductor laser device. As a method of reducing the ratio Pr/Pf in the semiconductor laser device, a method of increasing a reflectivity difference by reducing reflectivity of a reflective mirror (resonator mirror) at the side of the front facet and increasing reflectivity of a reflective mirror (resonator mirror) at the side of the rear facet is known.

Further, to reduce the internal loss, a technology for providing a layer with a high refractive index (also referred to as an electric field control layer) in an n-type cladding layer, and skewing a distribution of an electric field of laser light that propagates through an active layer to the n-type cladding layer side has been disclosed (Japanese Laid-open Patent Publication No. 2005-72402). With this technology, the laser light is less likely to be affected by light absorption by a p-type impurity (for example, zinc (Zn)) that is contained in a p-type cladding layer, so that it is possible to realize a semiconductor laser device with a reduced internal loss and higher output.

Furthermore, to realize low power consumption of the semiconductor laser device, it is important to reduce electrical resistance of the device. To reduce the electrical resistance, it is known that an increase in a cavity length or an increase in a width of an active layer in a buried-heterostructure semiconductor laser device is effective.

However, if the cavity length is increased or the reflectivity difference between the resonator mirrors is increased, a light distribution occurs in a resonator, so that a light density is increased at the side of the front facet at which the reflectivity is low, which leads to a phenomenon in which gain saturation occurs and optical power is reduced (spatial hole burning). To cope with this, as disclosed in Japanese Laid-open Patent Publication No. 2001-358405 for example, it is effective to reduce the light density by adopting a tapered waveguide (also referred to as a flared waveguide) as the active layer.

### SUMMARY

According to earnest examination made by the inventors of the present disclosure, if the tapered waveguide is adopted to the BH semiconductor laser device that includes the electric field control layer, an electric field confinement factor of laser light in the active layer largely varies depending on the width of the active layer, so that, in some cases, it may be difficult to achieve desired high output characteristics.

There is a need for a semiconductor laser device with high output.

According to one aspect of the present disclosure, there is provided a semiconductor laser device including: a main body including a first layer having n-type conductivity, a second layer having p-type conductivity, and an active layer interposed between the first layer and the second layer, the first layer, the second layer, and the active layer being laminated in a lamination direction; a front-side mirror formed on a front facet of the main body, the front facet being parallel to the lamination direction; and a rear-side mirror formed on a rear facet of the main body, the rear facet facing the front facet in an optical waveguide direction that crosses the lamination direction and the front facet, wherein the first layer includes an electric field control layer having a shorter composition wavelength than an emission wavelength of the active layer, the second layer includes an optical guide layer having a shorter composition wavelength than the emission wavelength of the active layer, the optical guide layer extending in the optical waveguide direction and having a smaller width than the active layer in a width direction perpendicular to the optical waveguide direction, buried layers made of a material having a lower refractive index than the optical guide layer are arranged at both sides of the optical guide layer in the width direction, and the optical guide layer includes a width-changed portion in which a width is changed in the optical waveguide direction.

### BRIEF DESCRIPTION OF THE DRAWINGS

FIG. 1 is a schematic top view of a semiconductor laser device according to an embodiment;

FIG. 2 is a cross-sectional view taken along a line A-A in FIG. 1;

FIG. 3 is a schematic top view of a semiconductor laser device according to a comparative example;

FIG. 4 is a cross-sectional view taken along a line B-B in FIG. 3;

FIG. 5 is a diagram illustrating an example of a relationship between a cavity length and a threshold carrier density;

FIG. 6 is a diagram illustrating an example of a relationship between an active layer width and Γact;

FIG. 7 is a diagram illustrating an example of a relationship between the cavity length and the threshold carrier density;

FIG. 8 is a diagram illustrating an example of a relationship between a guide layer width or the active layer width and Γact;

FIG. 9 is a diagram illustrating an example of a relationship between the cavity length and the threshold carrier density;

FIG. 10 is a diagram illustrating an example of a relationship between If and optical power; and

FIG. 11A to FIG. 11D are schematic diagrams illustrating a method of manufacturing the semiconductor laser device according to the embodiment.

### DETAILED DESCRIPTION

Embodiments will be described below with reference to the drawings. The present disclosure is not limited by the embodiments below. In addition, in description of the drawings, the same or corresponding components are appropriately denoted by the same reference symbols, and repeated explanation may be omitted. Further, it is necessary to note that the drawings are schematic, and dimensional relations between the components, ratios among the components, and the like may be different from actual ones. The drawings may include portions that have different dimensional relations or ratios. Furthermore, in the drawings, directions may be explained using the xyz Cartesian coordinate system.

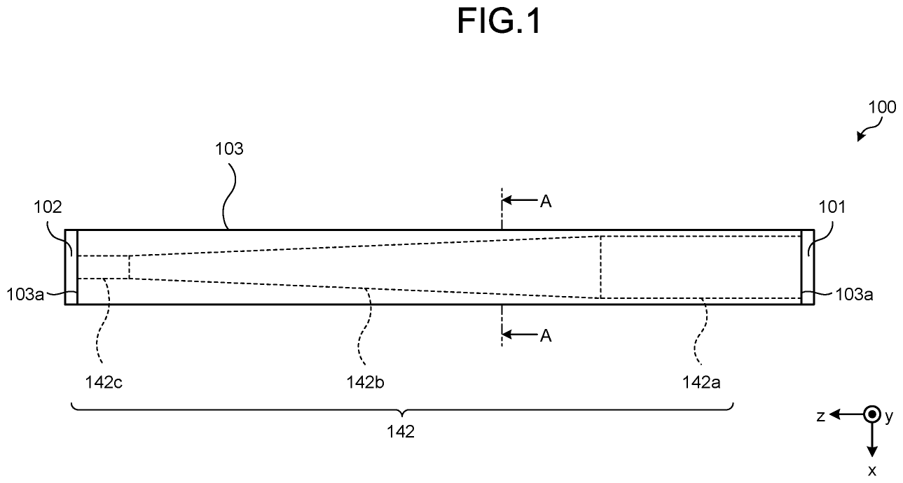

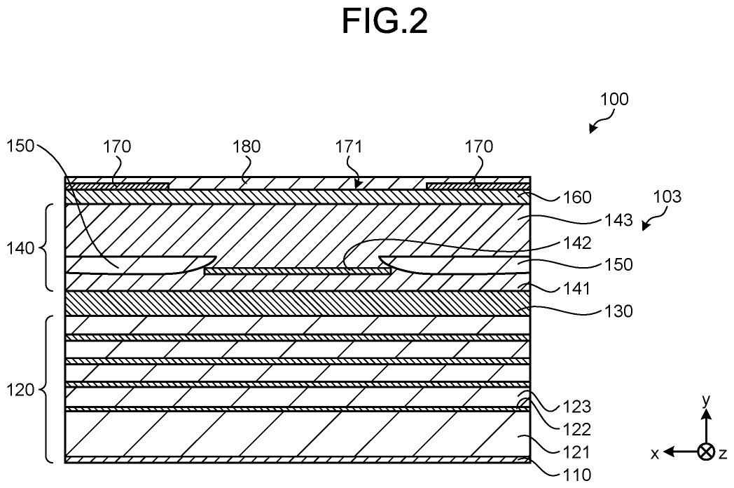

FIG. 1 is a schematic top view of a semiconductor laser device according to an embodiment. FIG. 2 is a cross-sectional view taken along a line A-A in FIG. 1.

A semiconductor laser device 100 includes a front-side mirror 101, a rear-side mirror 102, and a main body 103. The main body 103 extends in the z direction that is an optical waveguide direction, and includes a front facet 103a in the negative z direction and a rear facet 103b in the positive z direction. The front facet 103a and the rear facet 103b are formed by, for example, cleavage, are parallel to the xy plane, and face each other in the optical waveguide direction. The front-side mirror 101 is formed on the front facet 103a, and the rear-side mirror 102 is formed on the rear facet 103b. The front-side mirror 101 and the rear-side mirror 102 form a laser resonator.

A configuration of the main body 103 will be described with reference to FIG. 2. The main body 103 of the semiconductor laser device 100 includes a first layer portion 120 in which a first electrode 110 is formed on a back surface, an active layer 130, and a second layer portion 140, all of which are laminated in the y direction that is a lamination direction. The main body 103 further includes buried layers 150, a contact layer 160, a protection film 170, and a second electrode 180.

The first layer portion 120 is configured such that semiconductor layers with n-type conductivity are laminated, and has n-type conductivity. The second layer portion 140 has a structure in which semiconductor layers with p-type conductivity are laminated, and has p-type conductivity. The active layer 130 is interposed between the first layer portion 120 and the second layer portion 140.

The first layer portion 120 is configured such that a plurality of semiconductor layers are laminated by epitaxial growth or the like on a substrate 121 in which a buffer layer made of n-type indium phosphide (hereinafter, appropriately described as n-InP) is laminated on a substrate made of n-InP. The first layer portion 120 functions as a clad for the active layer 130.

The first layer portion 120 includes an electric field control layer 122 and an n-InP layer 123 that is a semiconductor layer made of n-InP. At least the single electric field control layer 122 is provided, and, for example, the four to seven electric field control layers 122 may be provided. The n-InP layer 123 is one example of a cladding layer.

Specifically, the first layer portion 120 is configured such that the electric field control layers 122 and the n-InP layers 123 are alternately laminated on the substrate 121. An n-type semiconductor layer in the present specification may contain, as an n-type impurity, silicon (Si), sulfur (S), or selenium (Se), for example.

The electric field control layer 122 is made of a semiconductor material with a shorter composition wavelength than an emission wavelength of the active layer 130. The composition wavelength is a wavelength of light corresponding to bandgap energy of the semiconductor material, and may also be referred to as a bandgap wavelength. The electric field control layer 122 is made of, for example, GaInAsP that is an InP based quaternary semiconductor material.

It is preferable that the semiconductor material that constitutes the electric field control layer 122 lattice-matches with InP. The lattice match indicates that lattice constants completely match with each other, or a semiconductor layer, such as the active layer 130, laminated on the electric field control layer 122 has a different lattice constant to the extent that demanded crystal quality is ensured. In this case, the crystal quality is, for example, a degree of dislocation, distortion, or a defect.

The active layer 130 has a multi quantum well-separate confinement heterostructure (MQW-SCH) structure that includes an MQW layer, which has an MQW structure including a plurality of barrier layers and a plurality of well layers, and two SCH layers, which are arranged so as to sandwich the MQW layer. The active layer 130 is made of, for example, GaInAsP. A composition ratio of a semiconductor material that constitutes the well layers of the active layer 130 is set such that light is emitted at a desired laser emission wavelength λc (for example, 1.55 μm band). A composition ratio of a semiconductor material that constitutes the barrier layers and the SCH layers is set so as to meet functions of the respective layers. Meanwhile, the active layer 130 may have a single quantum well structure.

The second layer portion 140 is configured such that a p-InP layer 141 that is made of p-type InP, an optical guide layer 142, and a p-InP layer 143 are sequentially laminated. The second layer portion 140 functions as a clad for the active layer 130. A p-type semiconductor layer in the present specification may contain, as a p-type impurity, zinc (Zn), for example. The p-InP layers 141 and 143 are one examples of the cladding layer.

The optical guide layer 142 is made of a semiconductor material with a shorter composition wavelength than the emission wavelength of the active layer 130. The optical guide layer 142 extends in the optical waveguide direction (z direction). The optical guide layer 142 is made of, for example, GaInAsP.

The buried layers 150 that are made of a material with a lower refractive index than the optical guide layer 142 are arranged at both sides of the optical guide layer 142 in a width direction (x direction). The buried layers 150 are made of n-InP. With this configuration, the optical guide layer 142 has a smaller width than the active layer 130 in the width direction.

Furthermore, as illustrated in FIG. 1, the width of the optical guide layer 142 is changed in the optical waveguide direction (z direction). Specifically, the optical guide layer 142 includes a wide-width straight portion 142a that has a constant width, a tapered portion 142b in which a width is changed in a tapered manner such that the width is reduced from the front facet 103a side to the rear facet 103b side, and a small-width straight portion 142c that has a constant width smaller than the wide-width straight portion 142a, all of which are sequentially arranged from the front facet 103a side to the rear facet 103b side. Therefore, in the optical guide layer 142, the width at the front facet 103a is larger than the width at the rear facet 103b. The tapered portion 142b is one example of a width-changed portion in which a width is changed in the optical waveguide direction.

It is preferable that the electric field control layer 122, the optical guide layer 142, and the barrier layers and the SCH layers of the active layer 130 are made of a semiconductor material (for example, GaInAsP) with the same composition, because it is possible to easily manage the composition at the time of manufacturing.

The contact layer 160 is formed on the p-InP layer 143. The contact layer 160 is made of, for example, GaInAsP, and comes in ohmic contact with the second electrode 180.

The protection film 170 is formed on the contact layer 160. The protection film 170 is made of dielectric, such as SiNx, for example. An opening 171 for establishing ohmic contact between the second electrode 180 and the contact layer 160 is formed in the protection film 170.

The second electrode 180 is arranged so as to come in ohmic contact with the contact layer 160. The second electrode 180 contains, for example, titanium, platinum, gold, or the like.

The first electrode 110 is arranged so as to come in ohmic contact with the substrate 121. The first electrode 110 contains, for example, gold, nickel, or the like.

Further, the front-side mirror 101 and the rear-side mirror 102 illustrated in FIG. 1 are dielectric films, for example. The front-side mirror 101 has reflectivity of 1% or less at the emission wavelength of the active layer 130, for example. The rear-side mirror 102 has reflectivity of 90% or more at the emission wavelength of the active layer 130, for example.

The semiconductor laser device 100 emits laser by light emission and optical amplification of the active layer 130 and action of the laser resonator of the front-side mirror 101 and the rear-side mirror 102, and outputs laser light mainly from the front-side mirror 101 side.

In this case, in the main body 103, the active layer 130, the electric field control layer 122, and the optical guide layer 142 contribute to confine the laser light. For example, in the lamination direction, the laser light is mainly confined in the active layer 130, and the electric field control layer 122 skews a distribution of an electric field of the laser light to the n-type first layer portion 120 side. As a result, the laser light is less likely to be affected by light absorption by a p-type impurity that is contained in the second layer portion 140, so that an internal loss is reduced.

Furthermore, in the width direction, the optical guide layer 142 mainly defines light confinement. The optical guide layer 142 is located at the side of the front facet 103a and has a relatively large width, so that a light density is reduced at the side of the front facet 103a and reduction of the optical power is prevented.

Here, according to the earnest examination made by the inventors of the present disclosure, if the width of the active layer is changed in order to reduce the light density or the like in the configuration in which the semiconductor laser device includes the electric field control layer, an electric field confinement factor of the laser light in the active layer largely varies depending on the width of the active layer, so that in some cases, it may be difficult to achieve desired high output characteristics.

In contrast, in the semiconductor laser device 100, the width of the optical guide layer 142 rather than the active layer 130 is changed in order to reduce the light density, so that a problem that the electric field confinement factor of the laser light in the active layer largely varies depending on the width of the active layer 130 does not occur. As a result, the semiconductor laser device 100 achieves high output.

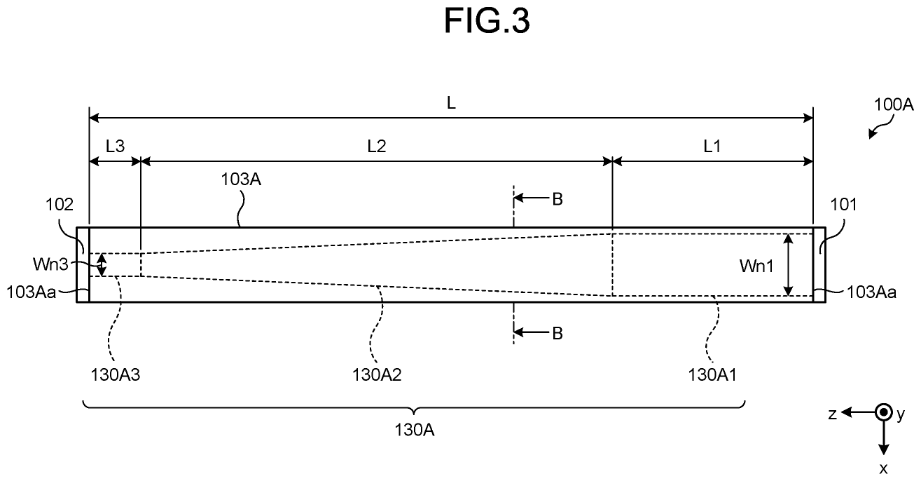

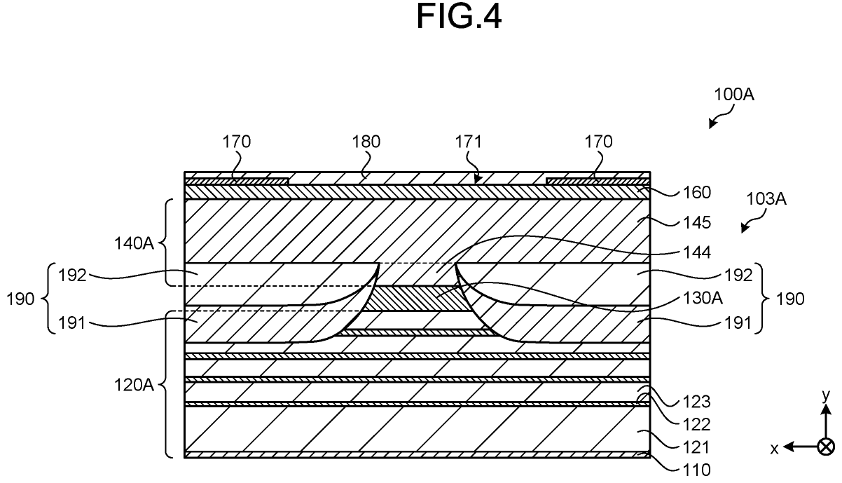

Characteristics of the semiconductor laser device 100 will be described below by comparison with characteristics of a semiconductor laser device of a comparative example having a well-known configuration. FIG. 3 is a schematic top view of the semiconductor laser device according to the comparative example. FIG. 4 is a cross-sectional view taken along a line B-B in FIG. 3.

A semiconductor laser device 100A according to the comparative example is configured such that the main body 103 is replaced with a main body 103A in the configuration of the semiconductor laser device 100.

A configuration of the main body 103A will be described below with reference to FIG. 4. The main body 103A of the semiconductor laser device 100A includes a first layer portion 120A in which the first electrode 110 is formed on a back surface, an active layer 130A, and an second layer portion 140A, all of which are laminated in the y direction that is the lamination direction. The main body 103A further includes buried layers 190, the contact layer 160, the protection film 170, and the second electrode 180.

The first layer portion 120A is configured such that, similarly to the first layer portion 120 of the main body 103 of the embodiment, the electric field control layers 122 and the n-InP layers 123 are alternately laminated on the substrate 121. However, an upper side (the positive side in the y direction) of the first layer portion 120A has a mesa structure, and both sides of the mesa structure in a width direction are buried by the buried layers 190.

The active layer 130A is made of the same semiconductor material as the active layer 130 of the main body 103 of the embodiment, and has the same MQW-SCH structure. However, the active layer 130A forms a part of the mesa structure, and both sides in the width direction are buried by the buried layers 190. In other words, the semiconductor laser device 100A is a BH semiconductor laser device.

Furthermore, as illustrated in FIG. 3, a width of the active layer 130A is changed in the optical waveguide direction (z direction). Specifically, the active layer 130A includes a wide-width straight portion 130A1 that has a constant width, a tapered portion 130A2 in which a width is changed in a tapered manner such that the width is reduced from a front facet 103Aa side to a rear facet 103Ab side, and a small-width straight portion 130A3 that has a constant width smaller than the wide-width straight portion 130A1, all of which are sequentially arranged from the front facet 103Aa side to the rear facet 103Ab side. In FIG. 3, L represents a cavity length of the semiconductor laser device 100A, L1, L2, and L3 represent lengths of the wide-width straight portion 130A1, the tapered portion 130A2, and the small-width straight portion 130A3, respectively, and L=L1+L2+L3. The width of the wide-width straight portion 130A1 is denoted by Wn1 and the width of the small-width straight portion 130A3 is denoted by Wn3.

The second layer portion 140A is configured such that p-InP layers 144 and 145 are sequentially laminated. However, the p-InP layer 144 forms a part of the mesa structure, and both sides in the width direction are buried by the buried layers 190.

Each of the buried layers 190 includes a buried layer 191 that is made of p-InP and a buried layer 192 that is made of n-InP. In other words, the buried layers 190 have lower refractive indices than the active layer 130A.

The inventors of the present disclosure have calculated a relationship between the cavity length and a threshold carrier density with respect to the semiconductor laser device of the comparative example as described above. The threshold carrier density indicates a carrier density that is needed to cause the active layer 130A to generate a gain for emitting laser. Meanwhile, in the calculation, Wn1 is set to 10 μm, Wn3 is set to 4.2 μm, and L1:L2:L3=19:25:1.

Furthermore, to confirm the effect of the active layer 130A having the tapered shape, a calculation was performed for a straight type, as a reference example, in which Wn1 and Wn3 of the active layer 130A are the same. Meanwhile, to equalize a volume of the active layer 130 between the tapered type and the straight type, Wn1=Wn3=8.2 μm.

However, in the calculations of the comparative example and the reference example as described above, the calculations were performed based on the assumption that an electric field confinement factor Γact of laser light in the active layer is constant regardless of the width of the active layer.

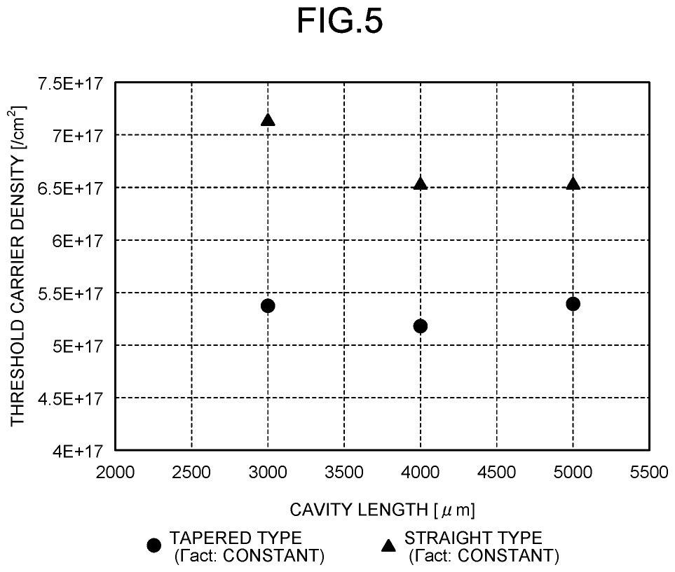

FIG. 5 is a diagram illustrating an example of a relationship between the cavity length and the threshold carrier density. The tapered type is the comparative example and the straight type is the reference example. Meanwhile, “E” represents exponentiation of 10, so that, for example, “5.5E+17” represents “5.5×10¹⁷”. As illustrated in FIG. 5, it may be understood that, as a result of preventing spatial hole burning, the threshold carrier density is reduced, at any cavity length, in the tapered type that is the comparative example. In other words, it may be understood that the tapered type may more easily achieve high output.

However, the inventors of the present disclosure found that Γact largely varies depending on the active layer width in the comparative example as a result of a calculation of the confinement factor Γact.

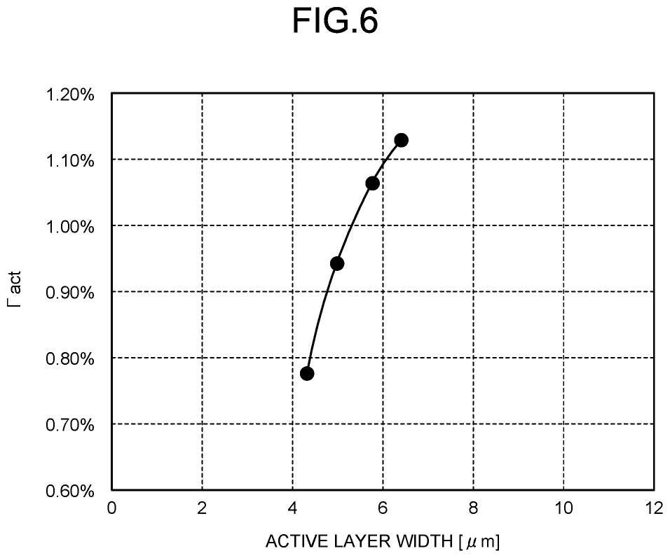

FIG. 6 is a diagram illustrating an example of a relationship between the active layer width and Γact. It may be understood from FIG. 6 that Γact largely varies depending on the active layer width.

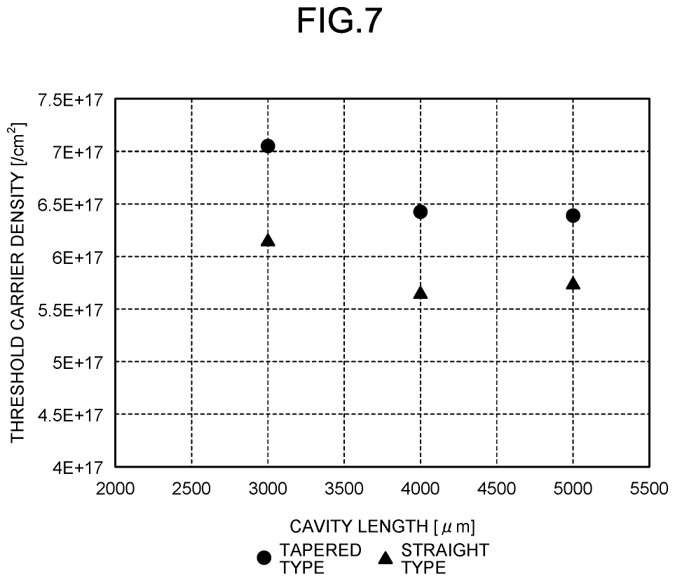

Therefore, the relationship between the cavity length and the threshold carrier density was re-calculated by taking into account a change of Γact, and a result as illustrated in FIG. 7 was obtained. As illustrated in FIG. 7, it may be understood that, if a change of Γact is taken into account, the threshold carrier density is reduced, at any cavity length, in the straight type that is the reference example, which means that the tapered type is not effective.

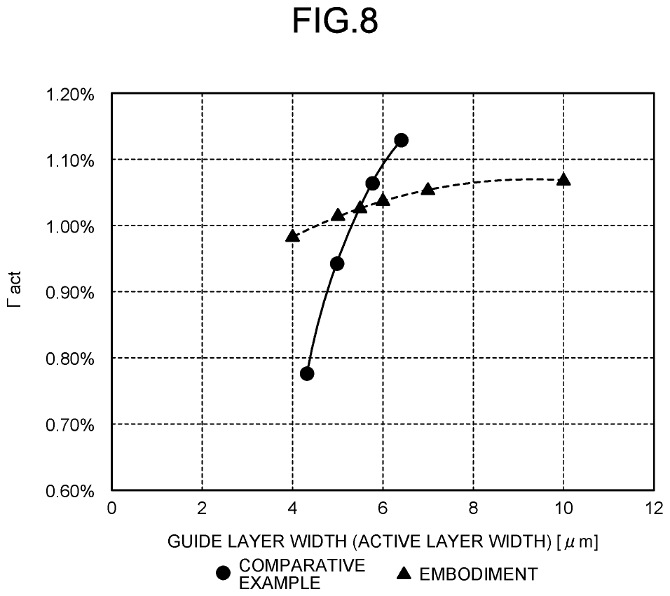

In contrast, FIG. 8 is a diagram illustrating an example of a relationship between a guide layer width (the width of the optical guide layer 142) of the embodiment or the active layer width of the comparative example and Γact. It may be understood from FIG. 8 that, in the embodiment, Γact is less dependent on the guide layer width.

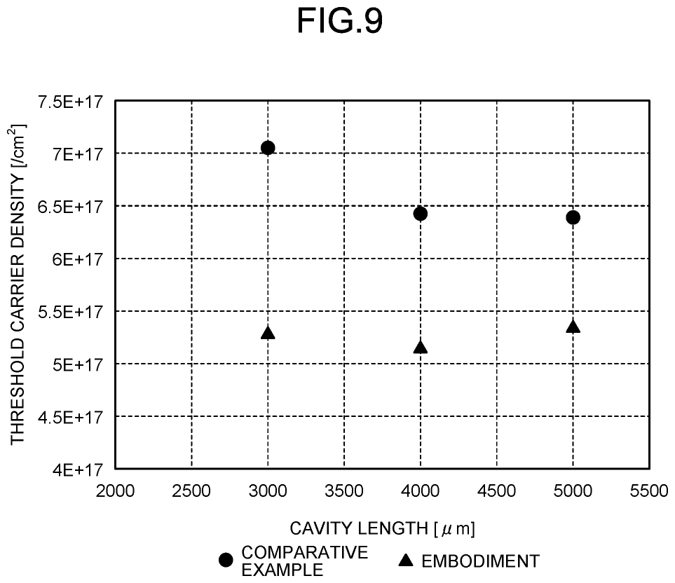

The relationship between the cavity length and the threshold carrier density was re-calculated by taking into account a change of Γact, and a result as illustrated in FIG. 9 was obtained. Meanwhile, in the calculation, the same conditions are adopted for Wn1, Wn3, L1, L2, and L3 between the embodiment and the comparative example. In other words, Wn1 is set to 10 μm, Wn3 is set to 4.2 μm, and L1:L2:L3=19:25:1. As illustrated in FIG. 9, it may be understood that the threshold carrier density is reduced, at any cavity length, in the straight type of the embodiment when the change of Γact is taken into account. As a result, it may be understood that the embodiment may more easily achieve high output.

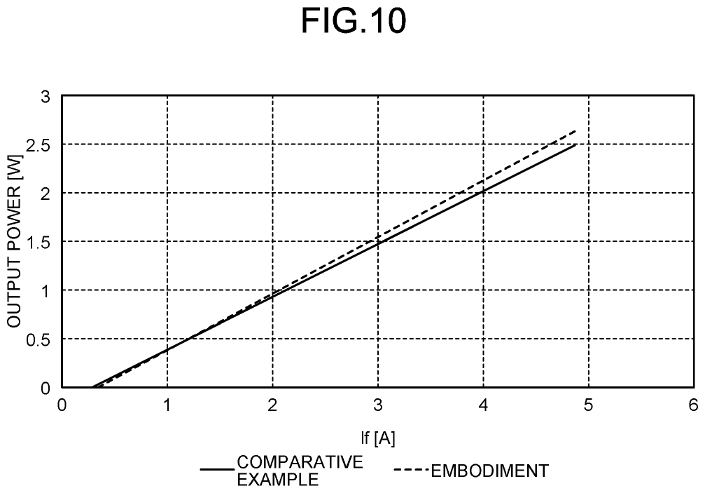

FIG. 10 is a diagram illustrating an example of a relationship between a forward current (If) and optical power in the embodiment and the comparative example. As illustrated in FIG. 10, higher output is achieved in the embodiment as compared to the comparative example with respect to the same If.

As described above, the semiconductor laser device 100 according to the embodiment is able to achieve high output.

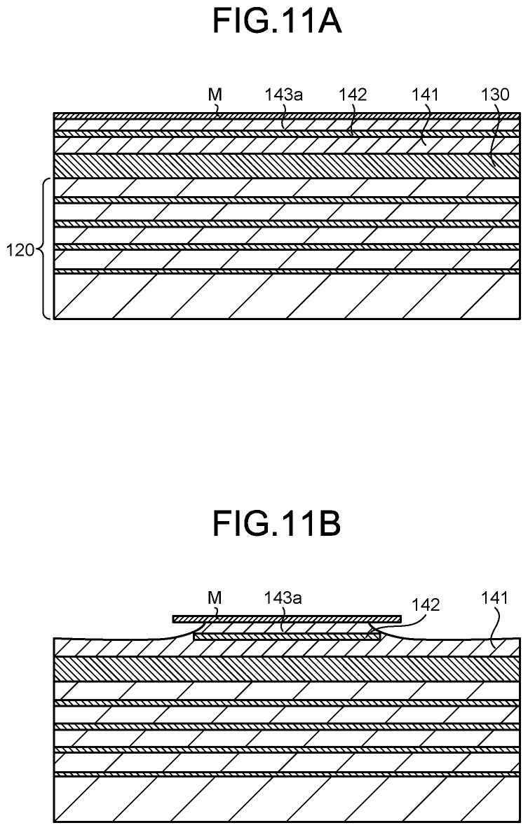

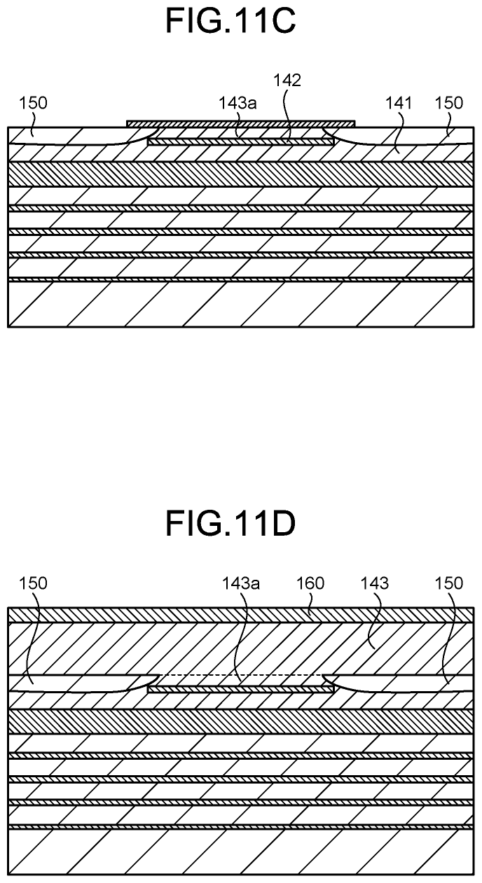

An example of manufacturing the semiconductor laser device 100 will be described below with reference to FIG. 11A to FIG. 11D. First, as illustrated in FIG. 11A, the first layer portion 120, the active layer 130, the p-InP layer 141, the optical guide layer 142, and a p-InP layer 143a that constitutes a part of the p-InP layer 143 are sequentially formed on the substrate 121 (see FIG. 2) by a crystal growth method, such as a Metal Organic Chemical Vapor Deposition (MOCVD) method, and thereafter a mask M that is made of a dielectric film is formed.

Subsequently, as illustrated in FIG. 11B, the mask M is formed in a certain shape with a slightly wider width than the optical guide layer 142 illustrated in FIG. 1 by a photolithography technique, and the p-InP layer 141, the optical guide layer 142, and the p-InP layer 143a are subjected to etching by using the mask M as an etching mask. An etching agent that is made of brominated gas may be used for the etching, for example.

Subsequently, as illustrated in FIG. 11C, the buried layers 150 are formed such that the p-InP layer 141, the optical guide layer 142, and the p-InP layer 143a are buried by using the mask M as a growth mask.

Subsequently, as illustrated in FIG. 11D, the mask M is removed, and the rest of the p-InP layer 143 and the contact layer 160 are sequentially formed on the entire surface.

Thereafter, the protection film 170 and the second electrode 180 are formed. Further, the substrate 121 is polished to have a desired thickness, and the first electrode 110 is formed on the entire back surface. Thereafter, well-known processes, such as cleavage, formation of the front-side mirror 101 and the rear-side mirror 102, cutting into a device piece, are preformed, and manufacturing of the semiconductor laser device 100 is completed.

Meanwhile, in the embodiment as described above, the tapered portion 142b is adopted as the width-changed portion in which the width is changed in the optical waveguide direction, but the width-changed portion is not limited to the tapered shape, and the width may be changed in a stepped manner.

Furthermore, in the embodiment as described above, the active layer 130 is made of GaInAsP that is an InP-based semiconductor material that does not contain aluminum, but may be made of a semiconductor material containing aluminum. In the manufacturing method as described above, the active layer 130 is not processed, and therefore, the active layer 130 may be made of a semiconductor material containing aluminum that is easily oxidized at the time of processing. Examples of the semiconductor material containing aluminum include AlGaInAs.

According to the present disclosure, it is possible to realize a semiconductor laser device with high output.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A semiconductor laser device comprising:
a main body including
a first layer having n-type conductivity,
a second layer having p-type conductivity, and
an active layer interposed between the first layer and the second layer,
the first layer, the second layer, and the active layer being laminated in a lamination direction;
a front-side mirror formed on a front facet of the main body, the front facet being parallel to the lamination direction; and
a rear-side mirror formed on a rear facet of the main body, the rear facet facing the front facet in an optical waveguide direction that crosses the lamination direction and the front facet, wherein
the first layer includes an electric field control layer having a shorter composition wavelength than an emission wavelength of the active layer,
the second layer includes an optical guide layer having a shorter composition wavelength than the emission wavelength of the active layer, the optical guide layer extending in the optical waveguide direction and having a smaller width than the active layer in a width direction perpendicular to the optical waveguide direction,
buried layers made of a material having a lower refractive index than the optical guide layer are arranged at both sides of the optical guide layer in the width direction, and
the optical guide layer includes a width-changed portion in which a width is changed in the optical waveguide direction.

2. The semiconductor laser device according to claim 1, wherein the width of the width-changed portion is changed in one of a tapered manner and a stepped manner.

3. The semiconductor laser device according to claim 1, wherein
the active layer has a quantum well structure including a well layer and a barrier layer, and includes a separate confinement heterostructure (SCH) layer, and
the electric field control layer, the optical guide layer, the barrier layer, and the SCH layer are made of a semiconductor material with same composition.

4. The semiconductor laser device according to claim 1, wherein
the front-side mirror has reflectivity of 1% or less at the emission wavelength of the active layer,
the rear-side mirror has reflectivity of 90% or more at the emission wavelength of the active layer, and
a width of the optical guide layer at the front facet is larger than a width of the optical guide layer at the rear facet.

5. The semiconductor laser device according to claim 1, wherein the active layer is made of a semiconductor material containing aluminum.

6. The semiconductor laser device according to claim 1, wherein each of the first layer portion and the second layer portion includes a cladding layer that is made of a same semiconductor material.
